(19) United States
(12) Patent Application Publication
(10) Pub. No.: US 2025/0271710 A1
(43) Pub. Date: Aug. 28, 2025

(54) CONDUCTIVE FILM AND DISPLAY DEVICE

(71) Applicant: TDK Corporation, Tokyo (JP)

(72) Inventors: Hiroshi SHINGAI, Tokyo (JP); Toshiaki KASAI, Tokyo (JP); Shinsuke HASHIMOTO, Tokyo (JP)

(73) Assignee: TDK Corporation, Tokyo (JP)

(21) Appl. No.: 19/208,779

(22) Filed: May 15, 2025

Related U.S. Application Data
(63) Continuation of application No. PCT/JP2023/039677, filed on Nov. 2, 2023.

(30) Foreign Application Priority Data
Nov. 18, 2022 (JP) 2022-184962

(51) Int. Cl. G02F 1/1343; G02F 1/1335

(52) U.S. Cl. CPC G02F 1/13439; G02F 1/133512; G02F 1/134318

(57) ABSTRACT

A conductive film includes a base material, and a conductive part provided over a main surface of the base material. The conductive part includes a main body part including a first metal, and a blackened layer configured to cover at least a surface of the main body part opposite to the base material, the blackened layer includes the first metal and a second metal different from the first metal, and the blackened layer has a crystalline structure with a space group of Pm-3m.

### CROSS-REFERENCE TO RELATED APPLICATIONS

This application is a continuation of PCT/JP2023/039677, filed on Nov. 2, 2023, which claims the benefit of priority based on Japanese Patent Application No. 2022-184962 filed on Nov. 18, 2022, and the entire contents of the above patent applications are incorporated herein by reference.

### TECHNICAL FIELD

The present disclosure relates to a conductive film and a display device.

### BACKGROUND ART

A display device including a display unit such as a touch panel may be provided with a conductive film having a conductive pattern with a conductive part formed in a mesh shape on the surface side of the display unit.

In such a conductive film, in order to reduce reflection of light from the conductive part, the conductive pattern may include a conductive main body and a blackened layer provided on the conductive main body.

For example, it is disclosed in Patent Literature 1 that a conductive film includes a substrate and a conductive part disposed on at least one main surface of the substrate and including a metal thin wire, in which the metal thin wire includes an underlying layer and a conductive layer disposed in this order from the substrate side, and a blackened layer covering a surface of the conductive layer, and has a line width of 2.0 μm or smaller, the underlying layer contains a metal oxide or a metal nitride as a main component, the blackened layer contains palladium, and the conductive layer contains copper as a main component.

### CITATION LIST

### Patent Literature

Patent Literature 1: WO 2019/065782 A

### SUMMARY

An aspect of the present disclosure provides a conductive film including:
a substrate;
a conductive part provided over a main surface of the base material, in which
the conductive part includes
a main body part including a first metal, and a blackened layer configured to cover at least a surface of the main body part opposite to the base material,
the blackened layer includes the first metal and a second metal different from the first metal, and
the blackened layer has a crystalline structure with a space group of Pm-3m.

### BRIEF DESCRIPTION OF DRAWINGS

FIG. 1 is a plan view illustrating an embodiment of a conductive film of the present disclosure.

FIG. 2 is a cross-sectional view taken along line II-II in FIG. 1.

FIG. 3 is a cross-sectional view illustrating a first structural body obtained in a first step.

FIG. 4 is a cross-sectional view illustrating a second structural body obtained in a second step.

FIG. 5 is a cross-sectional view illustrating a third structural body obtained in a third step.

FIG. 6 is a cross-sectional view illustrating a fifth structural body obtained in a fifth step.

FIG. 7 is a partial cross-sectional view illustrating an embodiment of a display device of the present disclosure.

FIG. 8 is a partial cross-sectional view illustrating another embodiment of the conductive film of the present disclosure.

### DESCRIPTION OF EMBODIMENTS

### Problem to be Solved by the Present Disclosure

The conductive film described in Patent Literature 1 has the following problems.

That is, in the conductive film described in Patent Literature 1, although reflection of light is reduced and the invisibility is improved, there is room for improvement in terms of conductivity.

The present disclosure has been made in view of the above problem, and an object of the present disclosure is to provide a conductive film and a display device capable of improving conductivity while reducing reflection of light.

### Effect of the Present Disclosure

According to the present disclosure, there are provided the conductive film and the display device capable of improving conductivity while reducing reflection of light.

Embodiments of the present disclosure will be described in detail below.

### <<Conductive Film>>

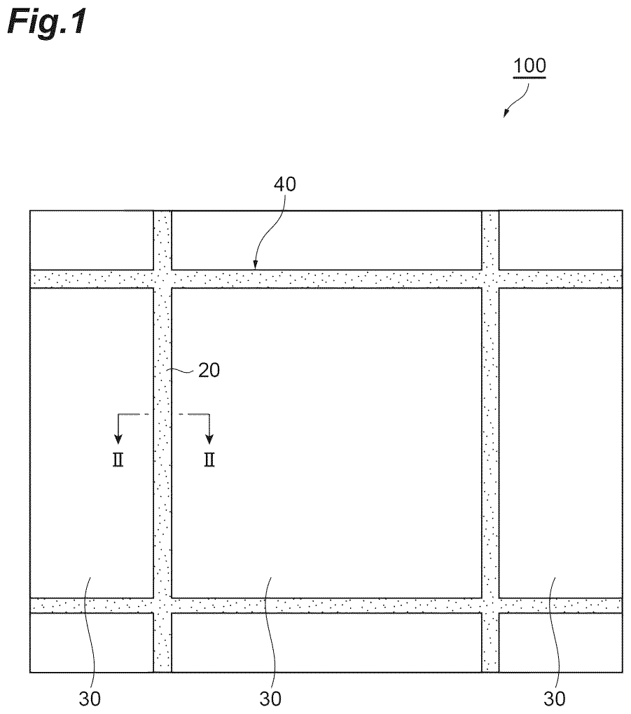

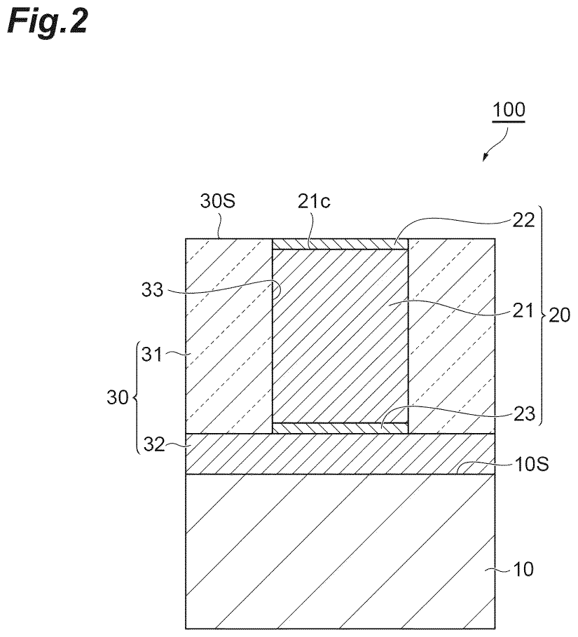

First, an embodiment of a conductive film of the present disclosure will be described with reference to the drawings. FIG. 1 is a plan view illustrating an embodiment of a conductive film of the present disclosure. FIG. 2 is a cross-sectional view taken along line II-II in FIG. 1.

A conductive film 100 illustrated in FIGS. 1 and 2 includes a base material 10, a mesh wiring 40 including a linear conductive part 20 provided over a main surface 10S of the base material 10, and a resin layer 30.

The resin layer 30 is provided on the main surface 10S of the base material 10, and has a trench 33 on the opposite side to the base material 10. The trench 33 is filled with the conductive part 20 that is secured to the base material 10 via the resin layer 30.

The conductive part 20 includes a main body part 21 including a first metal and a blackened layer 22 in this order. The blackened layer 22 is provided in the trench 33 and covers a first surface 21c serving as the surface of the main body part 21 opposite to the base material 10. The blackened layer 22 includes the first metal and a second metal different from the first metal, and the blackened layer 22 has a crystalline structure with a space group of Pm-3m.

According to this conductive film 100, since the blackened layer 22 covers the first surface 21c serving as the surface of the main body part 21 in the conductive part 20 provided over the main surface 10S of the base material 10, reflection of light is reduced by the blackened layer 22 even though light is incident on the main surface 10S of the base material 10. In addition, in a case where the main body part 21 contains the first metal, and the blackened layer 22 contains both the first metal and the second metal different from the first metal, and the blackened layer 22 has a crystalline structure with a space group of Pm-3m, the resistivity of the blackened layer 22 of the conductive part 20 is reduced, leading to a reduction in the overall resistivity of the conductive part 20. Therefore, the conductivity of the conductive film 100 can be improved. This is particularly effective in a case where the high-frequency current flowing through the conductive part 20 mainly flows on the surface of the conductive part 20 due to the skin effect. This is because, when the high-frequency current mainly flows on the surface of the conductive part 20, the resistivity of the blackened layer 22 constituting a part of the surface of the conductive part 20 greatly affects the conductivity of the conductive part 20.

The inventors of the present disclosure speculate that the reason why the resistivity of the blackened layer 22 is reduced when the blackened layer 22 has a crystalline structure with a space group of Pm-3m is as follows.

That is, in the crystalline structure with a space group of Fm-3m, atoms of the second metal are randomly present, and the regularity of the crystalline structure is lowered. On the other hand, in the crystalline structure with a space group of Pm-3m, the atoms of the second metal exist in a specific lattice (place), and the regularity of the crystalline structure is increased. Therefore, in the blackened layer 22 having the crystalline structure with a space group of Pm-3m, it is considered that a low resistivity can be obtained without hindering the flow of electrons when a current flows.

In addition, the trench 33 of the resin layer 30 is filled with the conductive part 20. Therefore, the conductive part 20 is stably secured to the base material 10 by the resin layer 30, and the conductive part 20 is less likely to be separated from the base material 10.

Hereinafter, the base material 10, the conductive part 20, and the resin layer 30 will be described in detail.

### <Base Material>

The base material 10 is a member that secures the conductive part 20. The base material 10 may be a light transmissive base material. The light transmissive base material has, for example, light transmissivity to an extent required in a case where the conductive film 100 is included in the display device. Specifically, the total light transmittance of the base material 10 may be 90% to 100%. Alternatively, the base material 10 may have a haze of 0% to 5%.

The base material 10 may be, for example, a transparent resin film, and examples thereof include a film of polyethylene terephthalate (PET), polycarbonate (PC), polyethylene naphthalate (PEN), cycloolefin polymer (COP), or polyimide (PI). The base material 10 may be a glass substrate.

The thickness of the base material 10 may be 1 μm or greater, 10 μm or greater, or 20 μm or greater, and may be 500 μm or smaller, 200 μm or smaller, or 100 μm or smaller.

### <Conductive Part>

The conductive part 20 includes the main body part 21 and the blackened layer 22. The conductive part 20 may further include an underlying layer 23 on the base material 10 side of the main body part 21.

The width of the conductive part 20 is not particularly limited, but is preferably 4 μm or smaller, and more preferably 2 μm or smaller from the viewpoint of enhancing the invisibility. Meanwhile, the width of the conductive part 20 is preferably 0.5 μm or greater, and more preferably 0.8 μm or greater from the viewpoint of reducing the resistance of the conductive part 20.

Note that the width of the conductive part 20 specifically refers to a width in a direction orthogonal to the extending direction of the conductive part 20 when the conductive part 20 is viewed in plan view from the blackened layer 22 side.

In the mesh wiring 40, the interval (pitch) between the facing conductive parts 20 is not particularly limited, but is preferably 300 μm or smaller, and more preferably 200 μm or smaller from the viewpoint of enhancing conductivity. From the viewpoint of enhancing the invisibility, the pitch of the conductive part 20 may be, for example, 50 μm or greater, or 80 μm or greater.

### (Main Body Part)

The main body part 21 includes the first metal. The first metal is not particularly limited, and examples of the first metal include copper (Cu), gold (Au), and silver (Ag).

The main body part 21 may further contain a nonmetallic element such as phosphorus within a range in which appropriate conductivity is maintained.

The space group of the crystalline structure included in the main body part 21 is not particularly limited, but may be Pm-3m or Fm-3m, and is preferably Fm-3m.

The mass content of the first metal in the main body part 21 may be, for example, 50% by mass or greater, 55% by mass or greater, or 100% by mass.

The main body part 21 may include crystal grains. The maximum grain size of the crystal grains (crystal grain size) is not particularly limited, and is preferably 30 nm or smaller, and more preferably 25 nm or smaller. The maximum size of the crystal grains contained in the main body part 21 may be 5 nm or greater, or 8 nm or greater.

The “maximum size of the crystal grains” in the present disclosure refers to the maximum size among the sizes of 10 crystal grains included in the field of view when a region at any one point in the cross section in the thickness direction of the main body part 21 is observed with a transmission electron microscope (TEM).

Note that the size of the crystal grain refers to the distance between two points on the grain boundary of the crystal grains when the distance between these two points is at its maximum.

The thickness of the main body part 21 is appropriately set based on a resistivity required for the conductive part 20 and may be, but not particularly limited to, 1.0 μm or greater, 1.5 μm or greater, or 2.0 μm or greater, for example. The thickness of the main body part 21 may be 6.0 μm or smaller, 5.0 μm or smaller, or 4.0 μm or smaller.

It is preferable that the main body part 21 and the resin layer 30 are in direct contact with each other without the blackened layer 22 interposed therebetween at the entirety or part of the interface between the main body part 21 of the conductive part 20 and the resin layer 30.

In this case, even in a case where the high-frequency current flowing through the conductive part 20 flows on the surface layer portion of the conductive part 20 due to the skin effect, the proportion of the blackened layer 22 in the surface layer portion of the conductive part 20 is reduced, so that the conductivity of the conductive part 20 can be further improved.

It is illustrated in FIG. 2 that the main body part 21 and the resin layer 30 are in direct contact with each other without the blackened layer 22 interposed therebetween at the entire interface between the main body part 21 of the conductive part 20 and the resin layer 30.

The main body part 21 and the resin layer 30 may be in contact with each other with the blackened layer 22 interposed therebetween at a part of the interface between the main body part 21 of the conductive part 20 and the resin layer 30.

### (Blackened Layer)

The blackened layer 22 contains the first metal and the second metal different from the first metal.

As the first metal, the same metal as the first metal contained in the main body part 21 is used.

The second metal may be a metal different from the first metal, but preferably has a lower reflectance in the visible light region than the first metal. Examples of the second metal include palladium (Pd) and nickel (Ni).

In the blackened layer 22, for example, the first metal may be Cu and the second metal may be Pd.

The mass content of the first metal in the blackened layer 22 is not particularly limited, and is preferably 50% by mass or greater. In this case, the resistivity of the blackened layer 22 tends to be reduced. The mass content of the first metal in the blackened layer 22 may be 53% by mass or greater, or 55% by mass or greater. The mass content of the first metal in the blackened layer 22 may be 95% by mass or smaller, 90% by mass or smaller, or 85% by mass or smaller.

The mass content of the second metal in the blackened layer 22 may be 15% by mass or greater, 20% by mass or greater, or 25% by mass or greater. The mass content of the second metal in the blackened layer 22 may be 50% by mass or smaller, 48% by mass or smaller, or 45% by mass or smaller. The mass content of the second metal in the blackened layer 22 is preferably 43% by mass or smaller.

The mass content of the first metal in the blackened layer 22 may be more than the mass content of the second metal in the blackened layer 22 or may be equal to or smaller than the mass content of the second metal, but it is preferable that the mass content of the first metal in the blackened layer 22 is more than the mass content of the second metal in the blackened layer 22, that is, a ratio R2 of the mass content of the first metal in the blackened layer 22 to the mass content of the second metal in the blackened layer 22 is more than 1.

In this case, since the space group of the crystalline structure contained in the blackened layer 22 is likely to be Pm-3m and the resistivity of the blackened layer 22 is effectively reduced, the resistivity of the conductive part 20 is effectively reduced as a whole. Therefore, the conductivity of the conductive film 100 can be effectively improved.

The ratio R2 is not particularly limited as long as it is more than 1, but is preferably 1.2 or greater, and more preferably 1.4 or greater. However, the ratio R2 is preferably 2.1 or smaller, and more preferably 2.0 or smaller.

The crystal system contained in the blackened layer 22 may be the same as or different from the crystal system of the first metal contained in the main body part 21, but is preferably the same. The crystal lattice belonging to the crystal system contained in the blackened layer 22 may be the same as or different from the crystal lattice of the first metal, but is preferably the same. In this case, the resistivity of the blackened layer 22 is effectively reduced. The crystal system varies depending on the type of the first metal, and examples thereof include cubic crystals and tetragonal crystals.

For example, in a case where the first metal is Cu, the crystal system of Cu is a cubic crystal and the crystal lattice is a face-centered cubic lattice (fcc). Thus, the crystal system contained in the blackened layer 22 is preferably a cubic crystal and the crystal lattice is a face-centered cubic lattice.

A compound forming the crystalline structure contained in the blackened layer 22 may be an intermetallic compound containing the first metal and the second metal. In a case where the first metal is Cu and the second metal is Pd, the intermetallic compound may be an intermetallic compound containing Cu and Pd. Examples of such an intermetallic compound include Cu_{3.82}Pd_{0.18}, Cu₃Pd, Cu₃PdPd, and CuPd. Among these, the intermetallic compound is preferably Cu_{3.82}Pd_{0.18}. In this case, since the resistivity of the blackened layer 22 is effectively reduced, the resistivity of the conductive part 20 is effectively reduced as a whole. Therefore, the conductivity of the conductive film 100 can be effectively improved.

The space group of the crystalline structure included in the blackened layer 22 is Pm-3m. In the blackened layer 22, the content of the crystalline structure with a space group of Pm-3m may be 70% by mass or greater, 80% by mass or greater, or 100% by mass.

The space group of the crystalline structure can be specified by observing an electron diffraction image of a region observed with a transmission electron microscope (TEM) in the cross section of the blackened layer 22 in the thickness direction. Specifically, in a case where the (110) plane exists in the electron diffraction image, it can be specified that the space group of the crystalline structure is Pm-3m.

The maximum size of the crystal grains contained in the blackened layer 22 is not particularly limited, and is preferably smaller than 30 nm, and more preferably 25 nm or smaller. In a case where the maximum size of the crystal grains contained in the blackened layer 22 is smaller than 30 nm, when light is incident on the conductive part 20, visible light is less likely to be scattered and is likely to be absorbed by the blackened layer 22 as compared with the case where the maximum size of the crystal grains contained in the blackened layer 22 is 30 nm or greater. Therefore, reflection of visible light at the conductive part 20 is effectively reduced. Therefore, the invisibility of the conductive part 20 can be enhanced.

The maximum size of the crystal grains contained in the blackened layer 22 may be 5 nm or greater, or 8 nm or greater.

The “maximum size of the crystal grains” in the present disclosure refers to the maximum size among the sizes of 10 crystal grains included in the field of view when a region at any one point in the cross section in the thickness direction of the blackened layer 22 is observed with TEM.

Note that the size of the crystal grain refers to the distance between two points on the grain boundary of the crystal grains when the distance between these two points is at its maximum.

The surface roughness of the blackened layer 22 is not particularly limited, and is preferably smaller than 100 nm, more preferably 80 nm or smaller, and more preferably 50 nm or smaller. In a case where the surface roughness of the blackened layer 22 is smaller than 100 nm, the flatness of the surface of the blackened layer 22 is increased, so that the resistivity of the blackened layer 22 can be further reduced. This is particularly effective in a case where the high-frequency current flowing through the conductive part 20 mainly flows on the surface of the conductive part 20 due to the skin effect.

Note that “100 nm” means much smaller than the lower limit of the wavelength of visible light.

The surface roughness of the blackened layer 22 may be 5 nm or greater, 10 nm or greater, or 15 nm or greater.

The “surface roughness” in the present disclosure is a maximum height, and specifically, is a value measured as a maximum height in a surface width of 300 nm of the blackened layer 22 when a cross section in the thickness direction of the blackened layer 22 is observed with TEM.

The surface roughness of the blackened layer 22 may be smaller than the surface roughness of the surface of the main body part 21 or equal to or greater than the surface roughness of the surface of the main body part 21, but is preferably smaller than the surface roughness of the surface of the main body part 21.

In this case, since the surface of the blackened layer 22 has flatness higher than that of the surface of the main body part 21 as compared with the case where the surface roughness of the blackened layer 22 is equal to or greater than the surface roughness of the surface of the main body part 21, the resistivity of the blackened layer 22 is further reduced. Therefore, the resistivity of the conductive part 20 is effectively reduced as a whole, and the conductivity of the conductive film 100 can be effectively improved. In particular, even in a case where the high-frequency current flowing through the conductive part 20 mainly flows on the surface of the conductive part 20 due to the skin effect, the influence of the surface of the blackened layer 22 is reduced, so that the conductivity of the conductive film 100 can be further improved.

A ratio R3 of the surface roughness of the blackened layer 22 to the surface roughness of the surface of the main body part 21 may be smaller than 1, but is preferably 0.9 or smaller, and more preferably 0.8 or smaller. However, the ratio R3 may be 0.2 or greater or 0.3 or greater.

The thickness of the blackened layer 22 is not particularly limited, and is preferably 100 nm or smaller, more preferably 80 nm or smaller, and more preferably 70 nm or smaller. In a case where the thickness of the blackened layer 22 is 100 nm or smaller, the resistivity of the entire conductive part 20 can be further reduced.

The thickness of the blackened layer 22 may be 10 nm or greater, 15 nm or greater, or 20 nm or greater.

### (Underlying Layer)

The underlying layer 23 contains a third metal.

The third metal may be a metal selected from Pd, Cu, Ni, Al, Co, Au, Ag, Pd, Rh, Pt, In, and Sn, a metal selected from Pd, Cu, Ni, and Al, a metal selected from Pd, Cu, and Ni, or Ni. The third metal may be one kind alone or a combination of two or more kinds. The third metal may be the same as or different from the first metal. For example, the third metal may be nickel, and the first metal may be copper.

The thickness of the underlying layer 23 may be 5 nm or greater, 10 nm or greater, or 30 nm or greater, and may be 500 nm or smaller, 300 nm or smaller, or 150 nm or smaller.

### (Resin Layer)

As illustrated in FIG. 2, the resin layer 30 may include a first resin layer 31. The first resin layer 31 contains a resin.

The total light transmittance of the first resin layer 31 may be 90% to 100%. The first resin layer 31 may have a haze of 0% to 5%.

The resin contained in the first resin layer 31 may be a cured product of a curable resin composition (photocurable resin composition or thermosetting resin composition). The curable resin composition contains a curable resin. Examples of a curable resin include an acrylic resin, an amino resin, a cyanate resin, an isocyanate resin, a polyimide resin, an epoxy resin, an oxetane resin, a polyester resin, an allyl resin, a phenolic resin, a benzoxazine resin, a xylene resin, a ketone resin, a furan resin, a condensed polycyclic polynuclear aromatic (COPNA) resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The thickness of the first resin layer 31 may be, for example, 500 nm or greater, 1,000 nm or greater, or 2,000 nm or greater, and may be 20 μm or smaller, 10 μm or smaller, or 5 μm or smaller.

### (Second Resin Layer)

As illustrated in FIG. 2, the resin layer 30 may further include a second resin layer 32 in addition to the first resin layer 31. The second resin layer 32 is provided between the first resin layer 31 and the base material 10.

The second resin layer 32 contains a resin. The second resin layer 32 may further include the first inorganic particles.

The resin contained in the second resin layer 32 may be a cured product of a curable resin composition (photocurable resin composition or thermosetting resin composition). The curable resin composition contains a curable resin. Examples of the curable resin include an acrylic resin, an amino resin, a cyanate resin, an isocyanate resin, a polyimide resin, an epoxy resin, an oxetane resin, a polyester resin, an allyl resin, a phenolic resin, a benzoxazine resin, a xylene resin, a ketone resin, a furan resin, a condensed polycyclic polynuclear aromatic (COPNA) resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether. The curable resin may be one kind alone or a combination of two or more kinds.

Examples of the first inorganic particles include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, barium silicate, boron nitride, calcium carbonate, barium sulfate, calcium sulfate, zinc oxide, magnesium titanate, hydrotalcite, mica, calcined kaolin, and carbon. The first inorganic particles may be used singly or in combination of two or more kinds thereof.

The second resin layer 32 is preferably formed of a material having higher adhesion to the base material 10 than the first resin layer 31.

The thickness of the second resin layer 32 may be, for example, 5 nm or greater, 100 nm or greater, or 200 nm or greater, and may be 10 μm or smaller, 5 μm or smaller, or 2 μm or smaller.

The resin layer 30 may further include second inorganic particles at least between the second resin layer 32 and the underlying layer 23. The second inorganic particles may be a metal selected from Pd, Cu, Ni, Al, Co, Au, Ag, Pd, Rh, Pt, In, and Sn, a metal selected from Pd, Cu, Ni, and Al, a metal selected from Pd, Cu, and Ni, or Pd. The second inorganic particles may be one kind alone or a combination of two or more kinds. The resin layer 30 may further include second inorganic particles between the second resin layer 32 and the first resin layer 31.

### (Trench)

In FIG. 2, the bottom surface of the trench 33 of the resin layer 30 is formed in the first resin layer 31. The trench 33 may be formed to penetrate the first resin layer 31.

### <<Method for Producing Conductive Film>>

Next, an embodiment of a method for producing a conductive film of the present disclosure will be described.

The method for manufacturing a conductive film of the present disclosure includes a conductive part-forming step of forming a conductive part over a main surface of a base material, in which in the conductive part-forming step, the conductive part includes a main body part containing a first metal and a blackened layer covering at least a surface of the main body part opposite to the base material, the blackened layer contains the first metal and a second metal different from the first metal, and the blackened layer is formed so as to have a crystalline structure with a space group of Pm-3m.

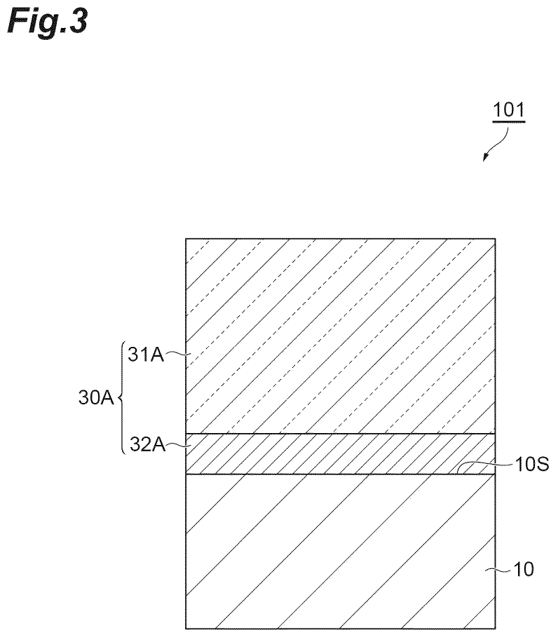

Hereinafter, a method for producing the conductive film 100 in a case where the conductive film is the above-described conductive film 100 will be described with reference to FIGS. 3 to 6.

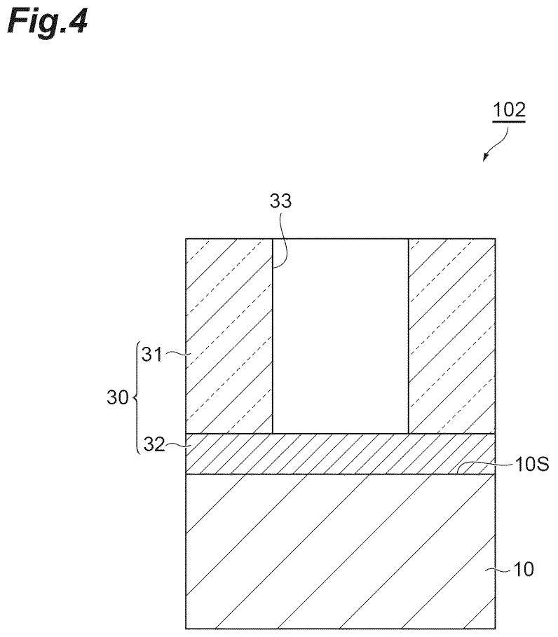

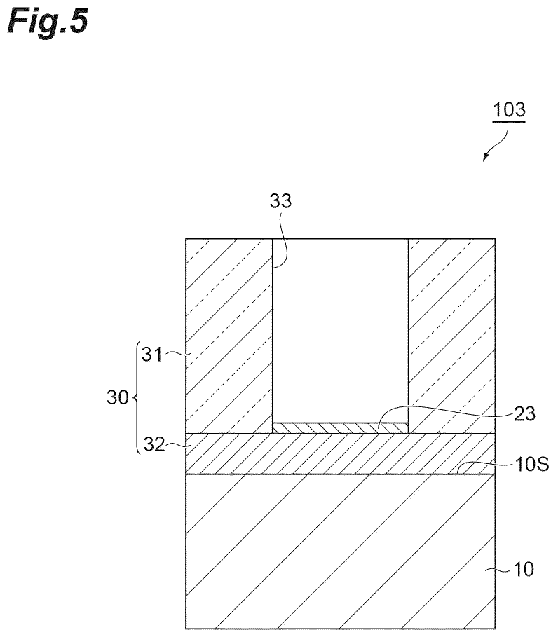

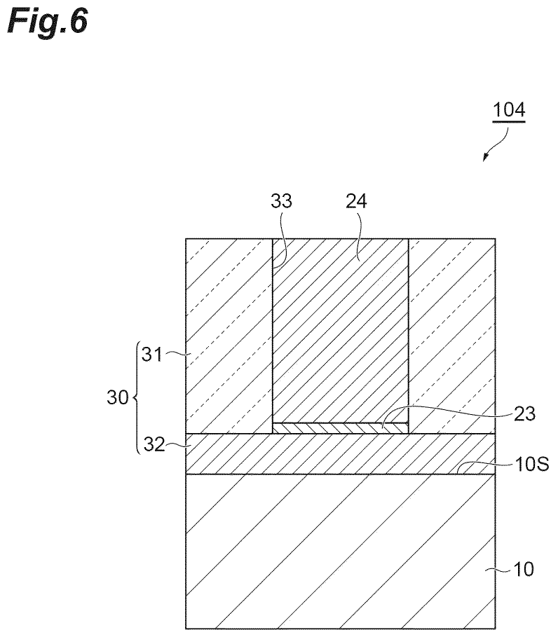

FIG. 3 is a cross-sectional view illustrating a first structural body obtained in a first step, FIG. 4 is a cross-sectional view illustrating a second structural body obtained in a second step, FIG. 5 is a cross-sectional view illustrating a third structural body obtained in a third step, and FIG. 6 is a cross-sectional view illustrating a fifth structure obtained in a fifth step.

The method for producing the conductive film 100 includes, for example, a first step of forming a resin film 30A on a main surface 10S of a base material 10 to obtain a first structural body 101 (see FIG. 3), a second step of forming a trench 33 by an imprinting method on a surface of the resin film 30A opposite to the base material 10 to form a resin layer 30, thereby obtaining a second structural body 102 (see FIG. 4), a third step of forming an underlying layer 23 as a seed layer containing a third metal in the trench 33 to obtain a third structural body 103 (see FIG. 5), a fourth step of forming a catalyst layer (not illustrated) on the underlying layer 23 in the third structural body 103 to obtain a fourth structural body, a fifth step of growing, by a plating method, a metal plating 24 containing the first metal on the underlying layer 23 to obtain the fifth structural body 104 (see FIG. 6), and a sixth step of blackening an exposed surface of the grown metal plating 24 with a blackening treatment solution containing the second metal to form the exposed surface layer portion of the metal plating 24 into a blackened layer 22, thereby forming a conductive part 20 including the underlying layer 23, the main body part 21, and the blackened layer 22 (see FIG. 2). Here, the third step to the sixth step correspond to the conductive part-forming step described above.

In the first step, the resin film 30A is a laminate including a second resin film 32A to be the second resin layer 32 and a first resin film 31A to be the first resin layer 31 (see FIG. 3).

In the first step, for example, first, the second resin film 32A containing first inorganic particles and a resin is formed, and a second inorganic particle-containing resin layer containing second inorganic particles as a nucleating agent and a resin is then formed. Thereafter, the resin is removed from the second inorganic particle-containing resin layer by ashing treatment. At this stage, the second inorganic particles as the nucleating agent remain on the surface of the second resin film 32A. Next, the first resin film 31A is formed on the second resin film 32A with the second inorganic particles interposed therebetween.

In the second step, for example, a mold having a protrusion is pushed into the resin film 30A, and the mold is then pulled out from the resin film 30A to form a trench 33 in the resin film 30A, resulting in the formation of the resin layer 30. At this stage, the trench 33 is formed so that the second inorganic particles present on the surface of the second resin film 32A are exposed, that is, so as to penetrate the first resin film 31A.

In a case where the first resin film 31A contains the curable resin composition, the first resin layer 31 may be formed by curing the first resin film 31A while the mold is pushed into the first resin film 31A. Specifically, in a case where the first resin film 31A contains the photocurable resin composition, the first resin film 31A may be irradiated with ultraviolet rays while the mold is pushed into the first resin film 31A to cure the first resin film 31A, thereby forming the first resin layer 31.

In the third step, the underlying layer 23 functions as a seed layer for growing the metal plating 24 in the fifth step. The underlying layer 23 can be formed by using the second inorganic particles on the second resin film 32A as a nucleating agent, for example, by immersing the second structural body 102 in an electroless plating solution for forming an underlying layer.

In the fourth step, the catalyst layer can be formed on the underlying layer 23 by immersing the third structural body 103 in a catalyst liquid containing a catalyst.

As the catalyst in the catalyst liquid, at least one metal selected from copper, nickel, cobalt, palladium, silver, gold, platinum, and tin can be used.

In the fifth step, for example, the metal plating 24 can be grown on the underlying layer 23 using the underlying layer 23 as a seed layer. The metal plating 24 is preferably grown by an electroless plating method. In this case, as compared with the case where the growth of the metal plating 24 is performed by the electrolytic plating method, grain boundaries and impurities are contained in the metal plating 24 in a relatively large amount, making it difficult for the second metal in the blackening treatment solution to diffuse into the metal plating 24 in the sixth step, and the blackened layer 22 containing the first metal more than the second metal can be formed in a short time. In a case where the metal plating 24 is grown by the electroless plating method, specifically, the metal plating 24 is grown on the underlying layer 23 starting from the catalyst layer by immersing the fourth structural body in, for example, an electroless plating solution.

In the sixth step, for example, the exposed surface of the grown metal plating 24 undergoes the blackening treatment with the blackening treatment solution containing the second metal to substitute a part of the first metal in the metal plating 24 with the second metal, resulting in the formation of the blackened layer 22 containing the first metal and the second metal.

The blackening treatment may be performed by bringing the metal plating 24 into contact with a blackening treatment solution containing the second metal. At this stage, in a case where the metal plating 24 is grown by the electroless plating method, the contact time between the metal plating 24 and the blackening treatment solution may be, for example, 150 seconds or shorter, or may be 120 seconds or shorter. Even though the contact time between the metal plating 24 and the blackening treatment solution is 100 seconds or shorter, the blackened layer 22 can be obtained.

The contact time between the metal plating 24 and the blackening treatment solution may be, for example, 30 seconds or longer, or 45 seconds or longer.

The temperature of the blackening treatment solution is not particularly limited, and may be, for example, 20° C. or higher or 25° C. or higher. The temperature of the blackening treatment solution may be, for example, 50° C. or lower, or may be 45° C. or lower.

In a case where the first metal is Cu and the second metal is Pd, and the compound represented by a composition formula of Cu_{3.18}Pd_{0.82} is formed in the blackened layer 22, the compound represented by the composition formula of Cu_{3.18}Pd_{0.82} can be formed in the blackened layer 22 even though the ratio of Pd to Cu is changed in a wide range. That is, the compound represented by the composition formula of Cu_{3.18}Pd_{0.82} can be easily formed in the blackened layer 22 without strictly controlling the ratio of Pd to Cu. Therefore, the contact time between the metal plating 24 and the blackening treatment solution, the temperature of the blackening treatment solution, and the like, which are necessary to adjust the ratio of Pd to Cu, can be set in a wide range.

### <<Display Device>

Next, an embodiment of a display device of the present disclosure will be described.

The display device of the present disclosure includes a conductive film. As the conductive film, the conductive film 100 described above can be used.

According to the display device, the conductive film can improve conductivity while reducing the reflection of light. Therefore, in the display device, the invisibility of the conductive part can be improved. In addition, the improvement of conductivity enables the suppression of heat generation by the conductive part.

The conductive film 100 can be used as, for example, a planar transparent antenna.

The display device may be, for example, a liquid crystal display device or an organic EL display device.

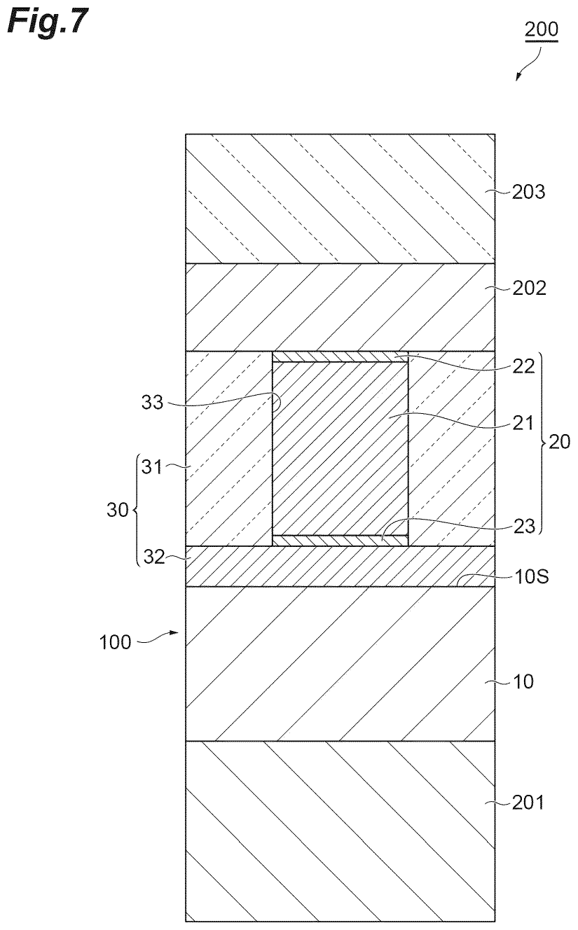

FIG. 7 is a cross-sectional view illustrating an embodiment of the display device of the present disclosure.

A display device 200 illustrated in FIG. 7 includes an image display unit 201, a conductive film 100, a polarizing plate 202, and a cover glass 203. The conductive film 100, the polarizing plate 202, and the cover glass 203 are laminated, in this order from the image display unit 201 side, on one surface side of the image display unit 201.

The configuration of the display device is not limited to the form of FIG. 7, and can be appropriately changed as necessary. For example, the polarizing plate 202 may be provided between the image display unit 201 and the conductive film 100. The image display unit 201 may be, for example, a liquid crystal display unit. As the polarizing plate 202 and the cover glass 203, those commonly used in a display device can be used. The polarizing plate 202 and the cover glass 203 are not necessarily provided.

The present disclosure is not limited to the above-described embodiments. For example, in the above-described embodiment, the conductive part 20 is secured to the base material 10 by the resin layer 30, but the conductive part 20 may be directly fixed to the base material 10. In this case, the resin layer 30 can be omitted.

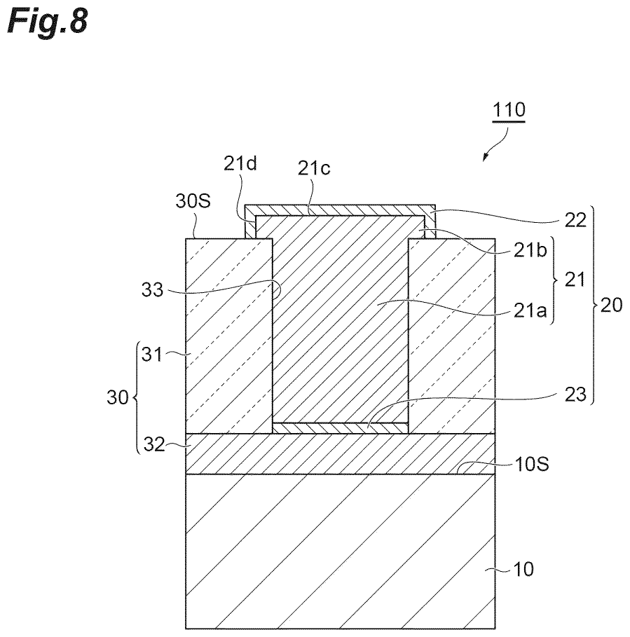

In the above embodiment, the main body part 21 of the conductive part 20 is formed with only a base portion provided inside the trench 33 when the conductive part 20 is viewed in a plan view (that is, when viewed in a direction orthogonal to the main surface 10S of the base material 10). However, as in the conductive film 110 illustrated in FIG. 8, the main body part 21 may include a base portion 21a and protruding portions 21b provided on both sides thereof.

In a case where the main body part 21 includes the base portion 21a and the protruding portions 21b provided on both sides of the base portion 21a, the protruding portions 21b are preferably in contact with the surface 30S of the resin layer 30 on the side opposite to the base material 10.

In this case, since the main body part 21 includes the protruding portions 21b provided on both sides of the base portion 21a, and the protruding portions 21b are in contact with the surface 30S of the resin layer 30 opposite to the base material 10, the contact area between the resin layer 30 and the conductive part 20 increases as compared with the case where the main body part 21 includes no protruding portions 21b. Therefore, adhesion between the resin layer 30 and the conductive part 20 is further improved, and the conductive part 20 is less likely to be separated from the resin layer 30. In addition, the thermal expansion coefficient of the conductive part 20 is generally smaller than the thermal expansion coefficient of the resin layer 30. Therefore, the base portion 21a is less likely to expand in the thickness direction than the resin layer 30. For this reason, even though the surrounding temperature increases and the resin layer 30 attempts to expand in the thickness direction thereof, the expansion of the resin layer 30 in the thickness direction is suppressed by the protruding portions 21b, and the conductive part 20 is less likely to be separated from the resin layer 30.

In a case where the main body part 21 includes the base portion 21a and the protruding portions 21b provided on both sides thereof, as illustrated in FIG. 8, the blackened layer 22 may cover the first surface 21c and the second surface 21d of the surface of the main body part 21. In this case, even though light is incident toward the main surface 10S of the base material 10, reflection of light is reduced by the blackened layer 22.

In the above embodiment, the bottom surface of the trench 33 of the resin layer 30 is formed in the first resin layer 31, but may be formed in the second resin layer 32 or the base material 10. In this case, as compared with the case where the bottom surface of the trench 33 is formed in the first resin layer 31, the aspect ratio of the conductive part 20 can be increased, and the conductivity of the conductive part 20 can be further improved. Here, the aspect ratio is a ratio of the thickness of the conductive part 20 to the width of the conductive part 20. The width of the conductive part 20 is a width in a direction orthogonal to the extending direction of the conductive part 20 when the conductive part 20 is viewed in plan view from the blackened layer 22 side, and the thickness of the conductive part 20 is a distance between a position closest to the base material 10 side and a position farthest from the base material 10 in the conductive part 20.

The present disclosure includes the following configuration examples in addition to the conductive film described in Solution to Problem, but is not limited to the following configuration examples.

In the conductive film according to one aspect of the present disclosure, in the blackened layer, the mass content of the first metal may be greater than the mass content of the second metal.

In this case, since the resistivity of the blackened layer is effectively reduced, the resistivity of the conductive part is effectively reduced as a whole. Therefore, the conductivity of the conductive film can be effectively improved.

In the conductive film, the first metal may be copper, and the second metal may be palladium.

In the conductive film, the blackened layer may contain a compound represented by a composition formula of Cu_{3.18}Pd_{0.82}.

In this case, since the resistivity of the blackened layer is effectively reduced, the resistivity of the conductive part is effectively reduced as a whole. Therefore, the conductivity of the conductive film can be effectively improved.

In the conductive film, the blackened layer may include crystal grains, and the maximum grain size of the crystal grains may be smaller than 30 nm.

In this case, when light is incident on the conductive part, visible light is less likely to be scattered and is more likely to be absorbed by the blackened layer. Therefore, reflection of visible light at the conductive part is effectively reduced. Therefore, it is possible to enhance the invisibility of the conductive part.

In the conductive film, a thickness of the blackened layer may be 100 nm or smaller.

In this case, since the thickness of the blackened layer is 100 nm or smaller, the resistivity of the entire conductive part can be further reduced.

In the conductive film, the surface roughness of the blackened layer may be smaller than 100 nm.

In this case, since the flatness of the surface of the blackened layer is increased, the resistivity of the blackened layer can be further reduced. This is particularly effective in a case where the high-frequency current flowing through the conductive part mainly flows on the surface of the conductive part due to the skin effect.

In the conductive film, the surface roughness of the blackened layer may be smaller than the surface roughness of the surface of the main body part.

In this case, since the surface of the blackened layer has flatness higher than that of the surface of the main body part as compared with the case where the surface roughness of the blackened layer is equal to or greater than the surface roughness of the surface of the main body part, the resistivity of the blackened layer is further reduced. Therefore, the resistivity of the conductive part is effectively reduced as a whole, and the conductivity of the conductive film can be effectively improved. In particular, even in a case where the high-frequency current flowing through the conductive part mainly flows on the surface of the conductive part due to the skin effect, the influence of the surface of the blackened layer is reduced, so that the conductivity of the conductive film can be further improved.

The conductive film may further include a resin layer provided over a main surface of the above-described base material, the resin layer may have a trench, and the conductive part may be filled in the trench.

In this case, in the conductive film, since the resin layer has the trench and the trench is filled with the conductive part, the conductive part is stably fixed to the base material.

In the conductive film, the main body part of the conductive part and the resin layer may be in direct contact with each other without the blackened layer interposed therebetween at least a part of the interface between the main body part and the resin layer.

In this case, even in a case where the high-frequency current flowing through the conductive part flows on the surface layer portion of the conductive part due to the skin effect, the proportion of the blackened layer in the surface layer portion of the conductive part is reduced, so that the conductivity of the conductive part can be further improved.

In the conductive film, the conductive part may include a base portion provided inside the trench and protruding portions provided on both sides of the base portion when viewed in a plan view of the conductive part, and the protruding portions may be in contact with a surface of the resin layer opposite to the base material.

In this case, since the main body part includes the protruding portions provided on both sides of the base portion, and the protruding portions are in contact with the surface of the resin layer opposite to the base material, the contact area between the resin layer and the conductive part increases as compared with the case where the main body part includes no protruding portions. Therefore, adhesion between the resin layer and the conductive part is further improved, and the conductive part is less likely to be separated from the resin layer. In addition, the thermal expansion coefficient of the conductive part is generally smaller than the thermal expansion coefficient of the resin layer. Therefore, the base portion is less likely to expand in the thickness direction than the resin layer. For this reason, even though the surrounding temperature increases and the resin layer attempts to expand in the thickness direction thereof, the expansion of the resin layer in the thickness direction is suppressed by the protruding portions, and the conductive part is less likely to be separated from the resin layer.

Another aspect of the present disclosure provides a display device including the conductive film.

According to the display device, the conductive film can improve conductivity while reducing reflection of light. Therefore, in the display device, the invisibility of the conductive part can be improved. In addition, the improvement of conductivity enables the suppression of heat generation by the conductive part.

### EXAMPLES

Although in the following, the present disclosure will be described more specifically with Examples, the present invention is not limited to the following Examples.

### Example 1

As a base material, a COP film (thickness: 100 μm) was prepared.

Next, a second resin composition containing silica as the first inorganic particles, an acrylic resin as a resin, and methyl ethyl ketone (MEK) as a solvent was applied onto the main surface of the base material, and dried to form a second resin film having a thickness of 0.3 μm.

Next, a Pd-containing resin composition containing Pd as the second inorganic particles, an acrylic resin as a resin, and methyl ethyl ketone (MEK) as a solvent was applied, and dried to form a Pd-containing resin layer having a thickness of 60 μm.

Subsequently, after the resin in the Pd-containing resin layer was removed by ashing treatment, a first resin composition containing an acrylic resin as a resin was applied onto the Pd particles remaining on the second resin film to form a first resin film having a thickness of 2 μm.

In this way, a resin film having a thickness of 2.3 μm was formed to obtain a first structural body.

Next, a trench was formed on a surface of the resin film opposite to the base material by an imprinting method to form a resin layer, thereby obtaining a second structural body. Specifically, a mold having a mesh-like protrusion was pushed into the resin film, and the mold was then pulled out from the resin film to form a mesh pattern having trenches each of which has a depth of 2 μm and a width of 1.5 μm in the resin film. At this stage, the Pd particles remaining on the second resin film were exposed. A resin layer was thus formed. At this stage, the pitch of the mesh pattern was 100 μm.

Next, the second structural body was immersed in an electroless plating solution containing nickel sulfate and sodium hypophosphite to grow Ni plating on the Pd particles remaining on the second resin film, and a Ni layer as an underlying layer was formed in the trench to obtain a third structural body. The third structure on which the Ni layer was formed was immersed in a Pd catalyst liquid to form a Pd catalyst layer, thereby obtaining a fourth structural body.

Next, the obtained fourth structural body was immersed in an electroless plating solution containing copper sulfate and formalin, and Cu plating was grown on the Ni layer starting from the Pd catalyst layer to form a Cu layer in the trench. As a result, a conductive layer having a mesh-like pattern was formed in the trench to obtain a fifth structural body.

Next, the fifth structural body was immersed in a blackening treatment solution containing palladium at room temperature (25° C.) for 60 seconds, and the blackening treatment was performed on the exposed surface of the grown copper plating to form a surface layer portion into a blackened layer, thereby forming a conductive part that includes an underlying layer, a main body part, and the blackened layer, resulting in the formation of a mesh wiring including the conductive part in a mesh pattern with trenches.

The conductive film was obtained as described above.

The conductive film obtained as described above was analyzed by TEM observation and electron diffraction to determine the thickness of the main body part, the composition ratio of Cu to Pd (Cu:Pd, mass ratio) in the blackened layer, the thickness of the blackened layer, the maximum size of crystal grains of the blackened layer, the crystalline structure (crystal lattice) of the blackened layer, the space group of the crystalline structure of the blackened layer, and the compound phase constituting the crystalline structure of the blackened layer. The results are illustrated in Table 1.

TEM observation and electron diffraction analysis were performed using a device (manufactured by JEOL Ltd., product name: JEM-2011F) equipped with an EDS detector in a scanning transmission electron microscope (STEM).

### Comparative Example 1

A conductive film was prepared in the same manner as in Example 1 except that the fifth structural body was immersed in a blackening treatment solution containing palladium at room temperature (25° C.) for 180 seconds.

The conductive film obtained as described above was analyzed by TEM observation and electron diffraction in the same manner as in Example 1 to determine the thickness of the main body part, the composition ratio of Cu to Pd (Cu:Pd, mass ratio) in the blackened layer, the thickness of the blackened layer, the maximum size of crystal grains of the blackened layer, the crystalline structure (crystal lattice) of the blackened layer, the space group of the crystalline structure of the blackened layer, and the compound phase constituting the crystalline structure of the blackened layer. The results are illustrated in Table 1.

### Comparative Example 2

A conductive film was prepared in the same manner as in Example 1 except that the blackening treatment was not performed and a blackened layer was not formed.

Regarding Comparative Example 2, since no blackened layer was formed, the thickness of the main body part, the composition ratio of Cu to Pd (Cu:Pd, mass ratio) in the blackened layer, the thickness of the blackened layer, the maximum size of crystal grains of the blackened layer, the crystalline structure (crystal lattice) of the blackened layer, the space group of the crystalline structure of the blackened layer, and the compound phase constituting the crystalline structure of the blackened layer were indicated by “-” in Table 1.

### <Evaluation>

### (1) Light Reflection Reducing Effect

In order to evaluate the light reflection reducing effect of the conductive films obtained in Example 1, Comparative Example 1, and Comparative Example 2, samples for evaluation were prepared. Specifically, the evaluation sample was prepared in the same manner as in Example 1, Comparative Example 1, or Comparative Example 2 except that the resin layer was not formed on the main surface of the base material and the conductive part was formed on the entire main surface of the base material. Then, for these samples for evaluation, the reflectance of light having a wavelength of 550 nm was measured with a spectrophotometer. The results are illustrated in Table 1.

### (2) Conductivity

A surface resistance value (22/sq) of the mesh wiring of the conductive film obtained in each of Example 1, Comparative Example 1, and Comparative Example 2 was measured using a four-terminal resistance measuring instrument, and the conductivity was evaluated from the surface resistance value. The results are illustrated in Table 1.

TABLE 1

| | | | | | | | | | Evaluation | |
|---|---|---|---|---|---|---|---|---|---|---|
| | | | Blackened layer | | | | | | Light reflection | Conductivity |
| | | | | | Maximum | | | | reducing effect | Surface |
| | | | | | size of | | | | Reflectance | resistance |
| | Main body part | | | | crystal | | | | at wavelength | value of |
| | Cu:Pd | Thickness | Cu:Pd | Thickness | grains | Crystalline | Space | Compound | of 550 nm | conductive part |
| | (mass ratio) | (μm) | (mass ratio) | (nm) | (nm) | structure | group | phase | (%) | (Ω/sq) |
| Example 1 | 100:0 | 2 | 62:38 | 40 | 23 | fcc | Pm-3m | Cu_{3.18}Pd_{0.82} | 10 | 0.2 |
| Comparative | 100:0 | 2 | 49:51 | 50 | 30 | fcc | Fm-3m | Cu and Pd | 10 | 0.4 |
| Example 1 | | | | | | | | solid solution | | |
| Comparative | 100:0 | 2 | — | — | — | — | — | — | 45 | — |
| Example 2 | | | | | | | | | | |

From the results illustrated in Table 1, it was found that in the conductive film of Example 1, the reflectance of light having a wavelength of 550 nm was equivalent to that in Comparative Example 1, but the surface resistance value of the conductive part was sufficiently reduced.

As described above, it has been confirmed that the conductive film of the present disclosure can improve conductivity while reducing light reflection.

The outline of the present disclosure is as follows.

[1] A conductive film including:
a substrate; and
a conductive part provided over a main surface of the base material, in which
the conductive part includes
a main body part including a first metal, and a blackened layer configured to cover at least a surface of the main body part opposite to the base material,
the blackened layer includes the first metal and a second metal different from the first metal, and
the blackened layer has a crystalline structure with a space group of Pm-3m.
   [2] The conductive film according to [1], in which a mass content of the first metal is greater than a mass content of the second metal in the blackened layer.
   [3] The conductive film according to [1] or [2], in which the first metal is copper, and the second metal is palladium.
   [4] The conductive film according to [3], in which the blackened layer contains a compound represented by a composition formula of Cu_{3.18}Pd_{0.82}.
   [5] The conductive film according to any one of [1] to [4], in which the blackened layer includes crystal grains, and a maximum grain size of the crystal grains is smaller than 30 nm.
   [6] The conductive film according to any one of [1] to [5], in which a thickness of the blackened layer is 100 nm or smaller.
   [7] The conductive film according to any one of [1] to [6], in which a surface roughness of the blackened layer is smaller than 100 nm.
   [8] The conductive film according to any one of [1] to [7], in which a surface roughness of the blackened layer is smaller than a surface roughness of a surface of the main body part.
   [9] The conductive film according to any one of [1] to [8], further including a resin layer provided over a main surface of the base material, in which the resin layer has a trench, and the trench is filled with the conductive part.
   [10] The conductive film according to [9], in which the main body part of the conductive part and the resin layer are in direct contact with each other without the blackened layer interposed therebetween at least a part of an interface between the main body part and the resin layer.
   [11] The conductive film according to [9] or [10], in which the main body part includes a base portion provided inside the trench and protruding portions provided on both sides of the base portion when viewed in a plan view of the main body part, and the protruding portions are in contact with a surface of the resin layer opposite to the base material.
   [12] A display device including the conductive film according to any one of [1] to [11].

### REFERENCE SIGNS LIST

10 Base material
10S Main surface
20 Conductive part
21 Main body part
21a Base portion
21b Protruding portion
22 Blackened layer
30 Resin layer
33 Trench
100 Conductive film
200 Display device.

1. A conductive film comprising:
a base material; and
a conductive part provided over a main surface of the base material, wherein
the conductive part includes
a main body part including a first metal, and a blackened layer configured to cover at least a surface of the main body part opposite to the base material,
the blackened layer includes the first metal and a second metal different from the first metal, and
the blackened layer has a crystalline structure with a space group of Pm-3m.

2. The conductive film according to claim 1, wherein a mass content of the first metal is greater than a mass content of the second metal in the blackened layer.

3. The conductive film according to claim 1, wherein the first metal is copper, and the second metal is palladium.

4. The conductive film according to claim 3, wherein the blackened layer contains a compound represented by a composition formula of Cu_{3.18}Pd_{0.82}.

5. The conductive film according to claim 1, wherein the blackened layer includes crystal grains, and a maximum grain size of the crystal grains is smaller than 30 nm.

6. The conductive film according to claim 1, wherein a thickness of the blackened layer is 100 nm or smaller.

7. The conductive film according to claim 1, wherein a surface roughness of the blackened layer is smaller than 100 nm.

8. The conductive film according to claim 1, wherein a surface roughness of the blackened layer is smaller than a surface roughness of a surface of the main body part.

9. The conductive film according to claim 1, further comprising a resin layer provided over a main surface of the base material, wherein
the resin layer has a trench, and the conductive part is filled in the trench.

10. The conductive film according to claim 9, wherein the main body part of the conductive part and the resin layer are in direct contact with each other without the blackened layer interposed therebetween at least a part of an interface between the main body part and the resin layer.

11. The conductive film according to claim 9, wherein
the main body part includes a base portion provided inside the trench and protruding portions provided on both sides of the base portion when viewed in a plan view of the main body part, and
the protruding portions are in contact with a surface of the resin layer on the side opposite to the base material.

12. A display device comprising the conductive film according to claim 1.
